(19) United States
(12) Patent Application Publication
(10) Pub. No.: US 2021/0343824 A1
(43) Pub. Date: Nov. 4, 2021

(54) DISPLAY DEVICE

(71) Applicant: Samsung Display Co., Ltd., Yongin si Gyeonggi-do (KR)

(72) Inventors: Sung-Gyu KIM, Cheonan-si (KR); Jong Won MOON, Cheonan-si (KR); Jong Han PARK, Seoul (KR); Min-Young SONG, Asan-si (KR); Chanyoon WOO, Cheonan-si (KR); Jungsoo YOUN, Seoul (KR)

(21) Appl. No.: 17/284,414

(22) PCT Filed: Jan. 25, 2019
(86) PCT No.: PCT/KR2019/001071

§ 371 Date: Apr. 9, 2021

(30) Foreign Application Priority Data
Oct. 16, 2018 (KR) 10-2018-0123325

(51) Int. Cl. H01L 27/32; G06F 3/041; H01L 51/52

(52) U.S. Cl. CPC H01L 27/3276; G06F 3/0412; H01L 27/323; G06F 2203/04102; H01L 51/5284; G06F 3/0416; H01L 51/5281

(57) ABSTRACT

A display device includes: a first substrate including a display area and a pad area; a second substrate facing the first substrate, a touch portion on the second substrate, a first flexible circuit board coupled to the first substrate, a second flexible circuit board coupled to the touch portion, a first adhesive layer on the first flexible circuit board, and a second adhesive layer that attaches the first adhesive layer and the second flexible circuit board to each other. The first adhesive layer and the second adhesive layer are formed of different materials from each other.

### CROSS-REFERENCE TO RELATED APPLICATIONS

This application is a U.S. National Phase Patent Application of International Patent Application Number PCT/KR2019/001071, filed on Jan. 25, 2019, which claims priority to Korean Patent Application Number 10-2018-0123325, filed on Oct. 16, 2018, the entire content of all of which is incorporated herein by reference.

### BACKGROUND

### 1. Field

The present disclosure relates to a display device, and, for example, to a display device capable of stably bonding a flexible circuit board providing a driving signal.

### 2. Description of Related Art

In general, a flat panel display device such as a liquid crystal display device or an organic light emitting display device includes a plurality of pairs of electric field generating electrodes and an electro-optical active layer therebetween. A liquid crystal display device includes a liquid crystal layer as the electro-optical active layer, and an organic light emitting display device includes an organic light emitting layer as the electro-optical active layer.

One of the pair of electric field generating electrodes is usually coupled to a switching element to receive an electric signal, and the electro-optical active layer converts the electric signal into an optical signal to display images.

In general, in such a flat panel display device, a touch portion may be formed, in an on-cell type, on a display panel which displays images, or a touch panel on the display panel may be provided.

Such a flat panel display device includes a flexible circuit board coupled to the display panel and a flexible circuit board coupled to the touch portion in order to apply a driving signal to the display panel and the touch portion.

In such a case, in order to secure the flexible circuit board of the display panel and the flexible circuit board of the touch portion to a rear surface of the display panel, the flexible circuit boards may be attached to each other using an adhesive.

This adhesive may be applied to one flexible circuit board in the form of a film, a release film may be removed, and then another flexible circuit board may be attached thereto.

However, in the process of removing the release film after applying the adhesive to the one flexible circuit board, the adhesive may not adhere to the flexible circuit board and may peel off together with the release film.

Accordingly, there is a need for a method in which the adhesive may be stably attached to the flexible circuit board.

### SUMMARY

Embodiments of the present disclosure are directed to a display device capable of stably securing two flexible circuit boards to a rear surface of a substrate by applying at least two layers of adhesives formed of different materials between the two flexible circuit boards to attach the two flexible circuit boards to each other.

According to an embodiment, a display device includes: a first flexible circuit board; a securing portion protruding and extending from one side of the first flexible circuit board; a first adhesive layer on the securing portion; a second adhesive layer on the first adhesive layer; and a second flexible circuit board on the second adhesive layer.

According to an embodiment, a display device includes: a first substrate including a display area and a pad area; a second substrate facing the first substrate; a touch portion on the second substrate; a first flexible circuit board coupled to the first substrate; a second flexible circuit board coupled to the touch portion; a securing portion extending from one selected from the first flexible circuit board and the second flexible circuit board; a first adhesive layer between the securing portion and the other selected from the first flexible circuit board and the second flexible circuit board; and a second adhesive layer between the first adhesive layer and the securing portion and formed of a material different from a material that forms the first adhesive layer.

In some embodiments, the first adhesive layer may include a filler including particles having a size in a range from 2 nm to 500 nm; and a binder binding the filler.

In some embodiments, the filler may include at least one selected from the group consisting of BaSO₄, TiO₂, SiO₂, and carbon black.

In some embodiments, the binder may include at least one selected from the group consisting of acrylic resins and epoxy resins.

In some embodiments, the first adhesive layer may have a thickness in a range from 5 to 15 μm.

In some embodiments, the first adhesive layer may include a first pattern configured to define an application area in a plan view.

In some embodiments, the first adhesive layer may include a second pattern applied in at least one of horizontal and vertical directions within the first pattern.

In some embodiments, the first adhesive layer may include a third pattern inside the first pattern while being spaced apart from the first pattern.

In some embodiments, the first adhesive layer may include a fourth pattern having a check pattern inside the first pattern.

In some embodiments, the second adhesive layer may include a pressure sensitive adhesive.

In some embodiments, an adhesive force between the first adhesive layer and the second adhesive layer may be in a range from about 2.0 kgf/in to about 3.0 kgf/in.

In some embodiments, an adhesive force between the first adhesive layer and the first flexible circuit board may be in a range from about 1.5 kgf/in to about 2.5 kgf/in.

In some embodiments, the securing portion may protrude from one side of one selected from the first flexible circuit board and the second flexible circuit board.

In some embodiments, the securing portion may be formed by cutting and bending a portion of one selected from the first flexible circuit board and the second flexible circuit board.

In some embodiments, the securing portion may overlap one side of one selected from the first flexible circuit board and the second flexible circuit board.

In some embodiments, the securing portion may be on a rear surface of the first flexible circuit board.

In some embodiments, the display device may further include a third adhesive layer between the second adhesive layer and the second flexible circuit board.

In some embodiments, the third adhesive layer may include a material substantially the same as a material that forms the first adhesive layer.

According to an embodiment, a display device includes: a first substrate including a display area and a pad area; a second substrate facing the first substrate; a touch portion on the second substrate; a first flexible circuit board coupled to the first substrate; a securing portion protruding and extending from one side of the first flexible circuit board; a second flexible circuit board coupled to the touch portion; a first adhesive layer on the securing portion; and a second adhesive layer that attaches the first adhesive layer and the second flexible circuit board to each other, wherein each of the first adhesive layer and the second adhesive layer comprises: a first pattern defining an application area; and a second pattern applied at a predetermined interval on the first flexible circuit board or on the second flexible circuit board in at least one of a horizontal direction and a vertical direction within the first pattern in a plan view.

According to one or more embodiments of the present disclosure, in a display device, at least two layers of adhesives are applied between flexible circuit boards to secure the flexible circuit boards stably, thereby preventing or reducing poor bonding between the flexible circuit boards.

### BRIEF DESCRIPTION OF THE DRAWINGS

FIG. 1 is a plan view schematically illustrating a structure of a display device according to an embodiment of the present disclosure.

FIG. 2 is a perspective view illustrating a display device according to an embodiment of the present disclosure.

FIG. 3 is a cross-sectional view taken along line I-I′ of FIGS. 1 and 2.

FIG. 4 is a plan view illustrating a securing portion according to another embodiment of the present disclosure.

FIG. 5 is a plan view illustrating a securing portion according to another embodiment of the present disclosure.

FIG. 6 is a partial cross-sectional view enlarging portion A of FIG. 3.

FIG. 7 is a plan view illustrating a first adhesive layer.

FIGS. 8A to 8C are plan views illustrating patterns in which a first adhesive layer is applied on a first flexible circuit board.

FIGS. 9A to 9D are process diagrams illustrating a process of attaching a second flexible circuit board on a first flexible circuit board.

FIG. 10 is a partial cross-sectional view enlarging portion A of FIG. 3 in a display device according to another embodiment of the present disclosure.

### DETAILED DESCRIPTION

Embodiments of the present disclosure will now be described more fully hereinafter with reference to the accompanying drawings. Advantages and features of embodiments of the present disclosure, and a method of achieving them will become apparent with reference to the embodiments described below in more detail together with the accompanying drawings. However, the subject matter of the present disclosure is not limited to the embodiments disclosed below but may be implemented in a variety of different forms, and these embodiments are only provided to make the present disclosure complete, and to fully inform the scope of the present disclosure to those skilled in the art, and the present disclosure is only defined by the scope of the claims, and equivalents thereof. Thus, in some embodiments, well-known process steps, well-known device structures, and well-known techniques have not been described in detail in order to avoid obscuring interpretation of the present disclosure. The same reference numerals refer to the same components throughout the specification.

Spatially relative terms “below”, “beneath”, “lower”, “above”, “upper”, etc., as illustrated in the drawings may be used to easily describe the correlation between the device or components and other devices or components. Spatially relative terms should be understood as terms including different directions of the device during use or operation in addition to the directions illustrated in the drawings. For example, if an element illustrated in the figure is turned over, an element described as “below” or “beneath” of another element may be placed “above” another element. Accordingly, the example term “below” may include both directions below and above. The device may be oriented in other directions as well, and thus spatially relative terms may be interpreted according to the orientation.

The terms used in the present specification are for describing embodiments and are not intended to limit the present invention. In this specification, the singular form also includes the plural form unless specifically stated in the phrase. As used in the specification, “includes” and/or “including” does not exclude the presence of one or more other components, steps, actions and/or elements in addition to the recited component, step, operation, and/or element.

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

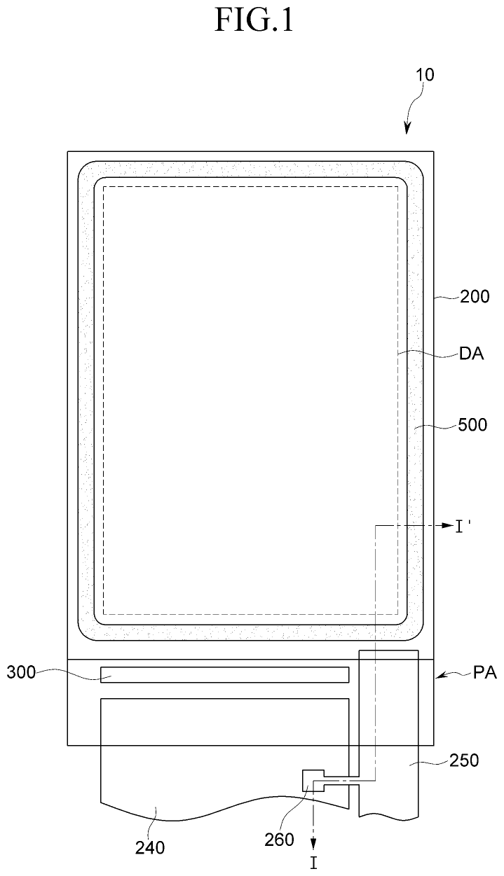

Hereinafter, a display device according to an embodiment of the present disclosure will be described in more detail with reference to FIGS. 1 to 3. The display device according to an embodiment of the present disclosure may be an organic light emitting display device (an organic light emitting diode (OLED) display device) or a liquid crystal display (LCD) device. Hereinafter, a case where the display device is an organic light emitting display device will be described.

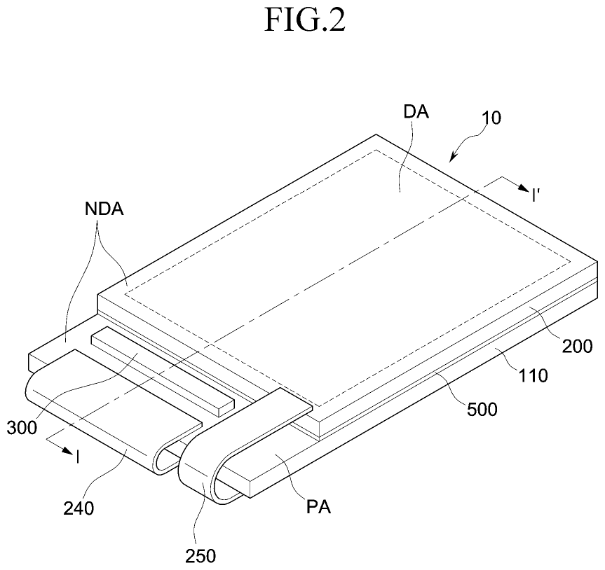

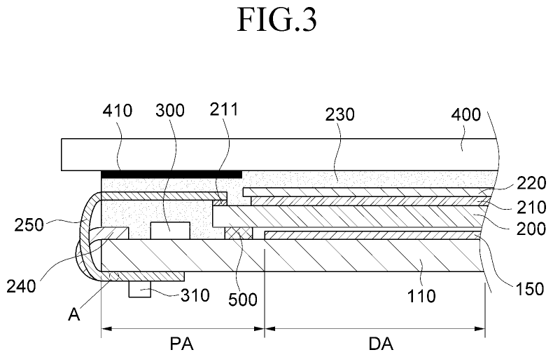

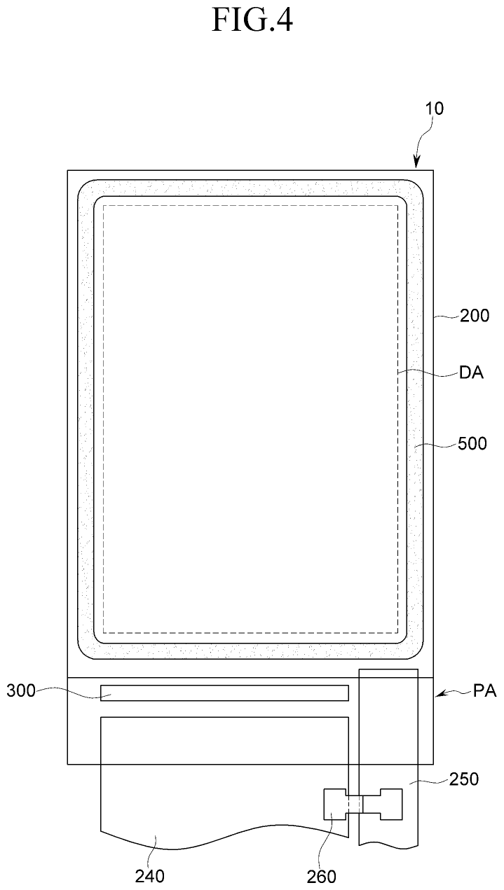

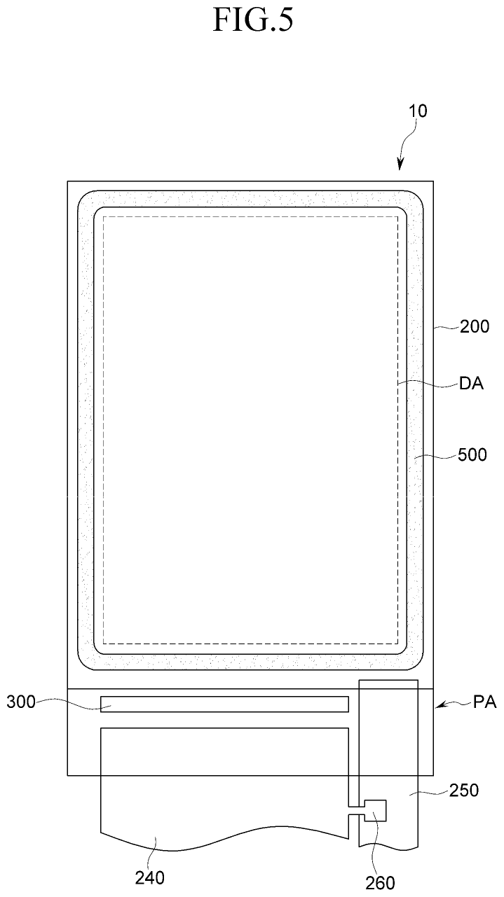

FIG. 1 is a plan view schematically illustrating a structure of a display device according to an embodiment of the present disclosure. FIG. 2 is a perspective view illustrating a display device according to an embodiment of the present disclosure. FIG. 3 is a cross-sectional view taken along line I-I′ of FIGS. 1 and 2. FIG. 4 is a plan view illustrating a securing portion according to another embodiment of the present disclosure. FIG. 5 is a plan view illustrating a securing portion according to another embodiment of the present disclosure.

Referring to FIGS. 1 and 3, a display device according to an embodiment of the present disclosure includes a first substrate 110, a display portion 150, a second substrate 200, a touch portion 210, a polarizing plate 220, a resin layer 230, a first flexible circuit board 240, a second flexible circuit board 250, a panel driver 300, a touch driver 310, a window 400, and a black matrix 410. In an embodiment, the first substrate 110, the display portion 150, the second substrate 200, the touch portion 210, and the polarizing plate 220 are collectively referred to as a display panel.

As illustrated in FIGS. 1 and 2, the display device 10 includes a first substrate 110 classified into a display area DA and a pad area PA. The first substrate 110 may include or be formed of a transparent glass material containing silicon oxide (SiO₂) as a main component. The first substrate 110 is not necessarily limited thereto and may be formed of a transparent plastic material. A plurality of pixels are formed in the display area DA of the first substrate 110 to display images, and one or more drivers 260 are formed in the pad area PA.

The first substrate 110 may further include a scan driver (not illustrated) and a data driver (not illustrated) for driving pixels. In addition, the first substrate 110 may further include pad electrodes (not illustrated) in the pad area PA. The panel driver 300 may be mounted in the pad area PA of the first substrate 110 in a chip on glass (COG) manner so as to be electrically coupled to the pad electrode (not illustrated). The first substrate 110 may further include wirings (not illustrated) coupling the panel driver 300 to the scan driver (not illustrated) and to the data driver (not illustrated). In an embodiment, the panel driver 300 is not necessarily formed in the non-display area NDA and may be omitted. A buffer member (not illustrated) that protects the panel driver 300 from external impact may be further in the pad area PA. The panel driver 300 may be a driving IC.

The display portion 150 is formed on the first substrate 110 and is coupled to the panel driver 300. The display portion 150 may include an organic light emitting element (OLED). In addition to the organic light emitting element, any element that may constitute a display device may be formed as the display portion 150.

The second substrate 200 faces the first substrate 110 and is bonded to the first substrate 110 using a sealant 500 as a medium. The second substrate 200 covers the display portion 150. Not only a glass substrate but also a transparent synthetic resin film such as acrylic (e.g., an acrylic resin or polymer) may be used as the second substrate 200, and further, a metal plate may be used. For example, the second substrate 200 may include at least one selected from a polyethylene (PET) film, a polypropylene (PP) film, a polyamide (PA) film, a polyacetal (POM) film, a polymethyl methacrylate (PMMA) film, a polybutylene terephthalate (PBT) film, a polycarbonate (PC) film, a cellulose film, and a moisture-proof cellophane.

The second substrate 200 may have an area smaller than an area of the first substrate 110. Accordingly, the pad area PA of the first substrate 110 may be exposed by the second substrate 200.

The sealant 500 may be a commonly used one such as, for example, a sealing glass frit.

The touch portion 210 is on the second substrate 200 corresponding to at least a portion of the display area DA of the first substrate 110. The touch portion 210 includes first and second electrodes (not illustrated) crossing each other. Each of the first and second electrodes may be patterned directly on the second substrate 200 in a matrix form in a plurality of rows to form an on-cell type. In addition, the touch portion 210 may be a separately manufactured touch panel and may be on the second substrate 200. The touch portion 210 includes a touch pad portion 211 on the second substrate 200. The touch driver 310 may drive and control the touch portion 210 and may be on the second flexible circuit board 250.

The touch portion 210 recognizes a touch by a touch means such as a pen or a user's finger and transmits a signal corresponding to the location where the touch is performed to the touch driver 310. The touch portion 210 may be used as an input means for the display device 10 and may be a pressure-sensitive or capacitive type.

In an embodiment, the first substrate may be encapsulated by an encapsulation layer, the second substrate may serve as a touch panel including a touch portion, and the first substrate and the second substrate may be attached to each other using an adhesive.

In addition, the touch portion 210 may be on the first substrate 110 corresponding to at least a portion of the display area DA. That is, the first electrode and the second electrode of the touch portion 210 may each be directly patterned on the first substrate 110 in a matrix form in a plurality of rows to form an in-cell type.

The first flexible circuit board 240 is coupled to the panel driver 300 to be coupled to the pad electrode (not illustrated) on the first substrate 110. For example, the first flexible circuit board 240 may be a flexible printed circuit board (FPCB). In more detail, the first flexible circuit board 240 may be mounted on the pad area PA in a chip on film (COF) manner. The first flexible circuit board 240 may include electronic elements (not illustrated) that process a driving signal and may further include a connector (not illustrated) that transmits an external signal to the panel driver 300. Electronic elements (not illustrated) may include a plurality of components that drive the display device 100, and may include, for example, DC-DC converters.

Referring to FIGS. 2 and 3, the first flexible circuit board 240 may be bent to cover one side of the first substrate 110. The first flexible circuit board 240 may be attached to a rear surface of the first substrate 110 using a double-sided tape (not illustrated) interposed therebetween.

The second flexible circuit board 250 is coupled to the touch pad portion 211 on the second substrate 200 to be coupled to the touch portion 210 and includes the touch driver 310. For example, the second flexible circuit board 250 may include an FPCB which is substantially equivalent to the first flexible circuit board 240. In more detail, the second flexible circuit board 250 may be mounted on the touch pad portion 211 of the second substrate 200 in a chip on film (COF) manner. The second flexible circuit board 250 includes electronic elements (not illustrated) that process a driving signal and may further include a connector (not illustrated) transmits an external signal to the touch driver 310. That is, the second flexible circuit board 250 couples a sensor pattern of the touch portion 210 and the touch driver 310.

Referring to FIGS. 2 and 3, the first flexible circuit board 240 and the second flexible circuit board 250 may be bent to cover one side of the first substrate 110. The second flexible circuit board 250 may be attached to a rear surface of the first substrate 110 using a double-sided tape (not illustrated) interposed therebetween. The touch driver 310 may be a touch driving IC.

Referring to FIG. 4, the second flexible circuit board 250 includes a securing portion 260 to be attached to the first flexible circuit board 240. The securing portion 260 protrudes and extends from one side of the second flexible circuit board 250. The securing portion 260 is attached to the first flexible circuit board 240 on a rear surface of the first substrate 110.

At least a portion of the first flexible circuit board 240 is attached to the securing portion 260 so that the first flexible circuit board 240 and the second flexible circuit board 250 are secured to each other on the side of a rear surface of the first substrate 110. That is, the securing portion 260 may be, for example, on the rear surface of the first substrate 110.

Referring to FIG. 4, the securing portion 260 may be bent by cutting a portion of the second flexible circuit board 250. In such a case, the securing portion 260 overlaps one side of the second flexible circuit board 250.

Herein above, it has been described that the second flexible circuit board 250 includes the securing portion 260, but embodiments of the present disclosure are not limited thereto. As illustrated in FIG. 5, the first flexible circuit board 240 may include the securing portion 260.

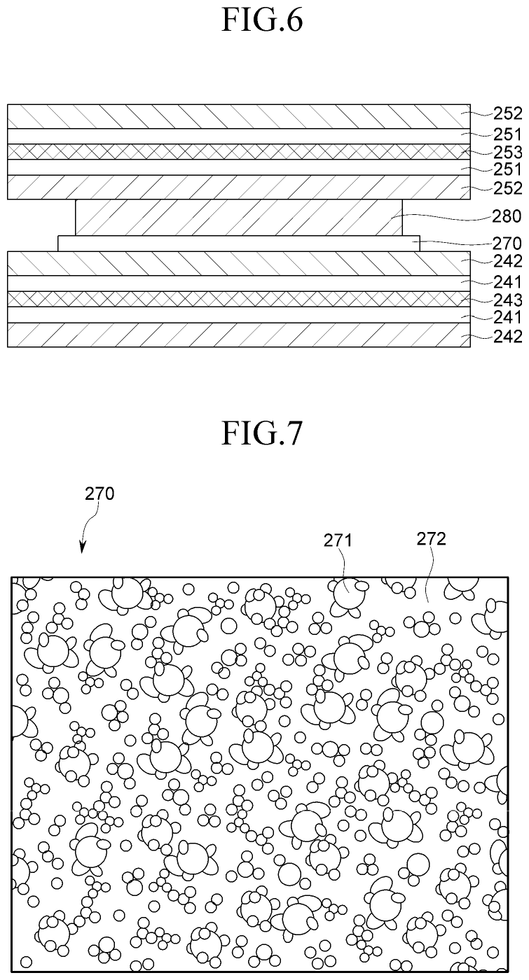

FIG. 6 is a partial cross-sectional view enlarging portion A of FIG. 3.

Referring to FIG. 6, the first flexible circuit board 240 (shown in FIG. 3) includes a first circuit wiring 241 and a first cover layer 242 on at least one surface of the first circuit wiring 241.

In the first circuit wiring 241, a first base 243 including or formed of polyimide and/or the like is provided in the center, and a first circuit pattern is on opposite surfaces of the first base 243 (e.g., surfaces that face away from each other).

The first cover layer 242 protects the first circuit wiring 241, and an adhesive layer (not illustrated) may be between the first circuit wiring 241 and the first cover layer 242.

In such an embodiment, the first cover layer 242 may be a photo solder resist (PSR) or a photoimageable coverlay (PIC).

The second flexible circuit board 250 (shown in FIG. 3) may include a second circuit wiring 251 and a second cover layer 252 on at least one surface of the second circuit wiring 251.

In the second circuit wiring 251, a second base 253 including or formed of polyimide and/or the like is provided in the center, and a second circuit wiring pattern is on opposite surfaces of the second base 253.

The second cover layer 252 protects the second circuit wiring 251, and an adhesive layer may be between the second circuit wiring 251 and the second cover layer 252.

In addition, the securing portion 260 (shown in FIG. 3) may have the same structure as the second flexible circuit board 250.

A first adhesive layer 270 and a second adhesive layer 280 may be between the securing portion 260 and the first flexible circuit board 240.

The first adhesive layer 270 and the second adhesive layer 280 may each have an area smaller than areas of the first flexible circuit board 240 and the securing portion 260 in a plan view. The first adhesive layer 270 has a thickness in a range from 5 to 15 μm.

The first adhesive layer 270 may be on at least a portion of the second flexible circuit board 240 and may be applied by a silk imprinting process and/or a deposition process. The first adhesive layer 270 may be applied over an entire surface of the securing portion 260, having an area corresponding to that of the securing portion 260, or may be applied in a predetermined pattern. An application pattern of the first adhesive layer 270 will be described in more detail below.

The first adhesive layer 270 is between the securing portion 260 of the second flexible circuit board 250 and the first flexible circuit board 240 so that the second adhesive layer 280 may be better attached to the first flexible circuit board 240.

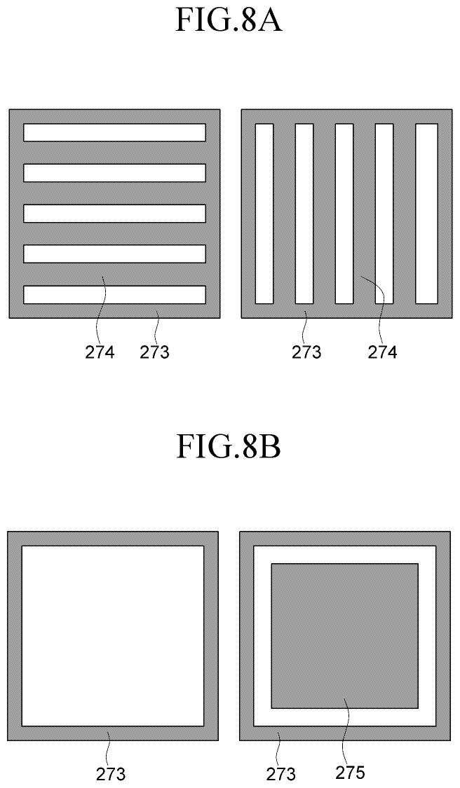

FIG. 7 is a plan view illustrating a first adhesive layer.

Referring to FIG. 7, the first adhesive layer 270 may include a filler 271 and a binder 272 binding the filler 271 to each other.

The filler 271 may include at least one selected from the group consisting of BaSO₄, TiO₂, SiO₂, and carbon black.

The filler 271 may have a size in a range from 2 nm to 500 nm, and may have a circular shape, a rod shape, and/or an irregular shape.

The binder 272 may include at least one selected from the group consisting of acrylic resins and epoxy resins.

In addition, the first adhesive layer 270 may further include a solvent capable of dissolving the binder 272. The solvent may be volatilized during the bonding process between the first flexible circuit board 240 and the second flexible circuit board 250 but may remain partially in the first adhesive layer 270.

The first adhesive layer 270 may improve adhesion to the first flexible circuit board 240 by performing plasma treatment on an upper surface thereof.

An adhesive force between the first adhesive layer 270 and the first flexible circuit board 240, more specifically, between the first adhesive layer 270 and the first cover layer 242, may be greater than about 1.5 kgf/in. For example, the adhesive force between the first adhesive layer 270 and the first flexible circuit board 240 may be in a range from about 1.5 kgf/in to about 2.5 kgf/in.

The second adhesive layer 280 is between the first adhesive layer 270 and the securing portion 260 and attaches the first adhesive layer 270 to the securing portion 260 of the second flexible circuit board 250. The second adhesive layer 280 may include or be formed of a material different from that of the first adhesive layer 270, for example, a pressure sensitive adhesive (PSA). For example, the second adhesive layer 280 may include an acrylic, silicone, and/or urethane-based material (e.g., an acrylic resin or polymer, a silicone resin or polymer, and/or a urethane-based resin or polymer).

An adhesive force between the first adhesive layer 270 and the second adhesive layer 280 may be greater than 2.0 kgf/in. For example, the adhesive force between the first adhesive layer 270 and the second adhesive layer 280 may be in a range from about 2.0 kgf/in to about 3.0 kgf/in. In a case where the adhesive force of the second adhesive layer 280 is greater than about 2.0 kgf/in, suitable or sufficient adhesive force may be provided to the first flexible circuit board 240.

An adhesive force between the second adhesive layer 280 and the second flexible circuit board 250, more specifically, between the second adhesive layer 280 and the second cover layer 252, may be greater than 0.3 kgf/inch. For example, the adhesive force between the second adhesive layer 280 and the second flexible circuit board 250 may be in a range from 0.3 kgf/inch to 1.5 kgf/inch.

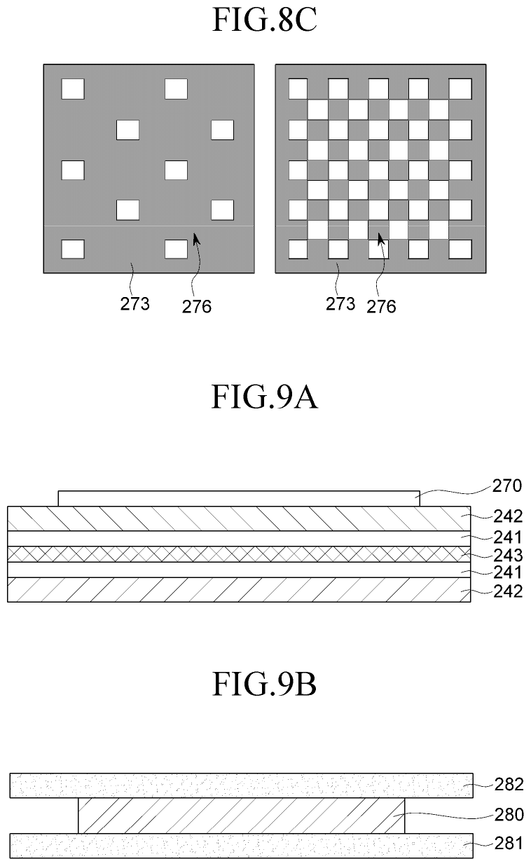

FIGS. 8A to 8C are plan views illustrating patterns in which a first adhesive layer is applied on a first flexible circuit board.

Referring to FIG. 8A, the first adhesive layer 270 may include a first pattern 273 defining an application area. In addition, the first adhesive layer 270 may include a second pattern 274 applied at a predetermined interval on the first flexible circuit board 240 in at least one of a horizontal direction and a vertical direction within the first pattern 273 in a plan view. This second pattern 274 may be perpendicular or parallel to a peeling direction of a release film.

Referring to FIG. 8B, the first adhesive layer 270 may include a first pattern 273 defining an application area, and the first adhesive layer 270 may not be applied inside the first pattern 273. In addition, the first adhesive layer 270 may include a third pattern 275 spaced apart from the first pattern 273 by a predetermined distance.

Referring to FIG. 8C, the first adhesive layer 270 may include a first pattern 273 defining an application area, and a part of the inside of the first pattern 273 may not be applied with the first adhesive layer 270 in dot shapes. In addition, the first adhesive layer 270 may include a fourth pattern 276 having a check pattern inside the first pattern 273.

In addition, in order to prevent an area at which the first flexible circuit board 240 and the second flexible circuit board 250 are attached to each other to be visually recognized, the first adhesive layer 270 may have the same color as those of the first flexible circuit board 240 and the second flexible circuit board.

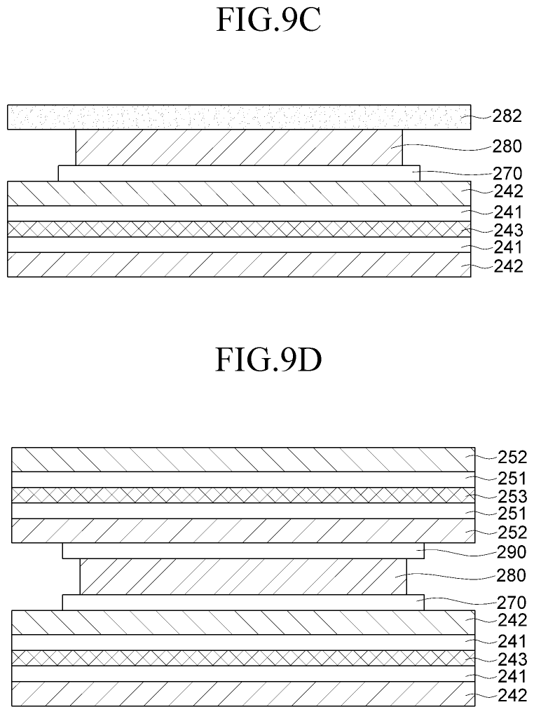

FIGS. 9A to 9C are process diagrams illustrating a process of attaching a second flexible circuit board on a first flexible circuit board.

Referring to FIG. 9A, the first adhesive layer 270 is applied on the first cover layer 242 of the first flexible circuit board 240 by a silk printing and/or deposition process.

Referring to FIG. 9B, an adhesive member is provided to apply the second adhesive layer 280 on the first adhesive layer 270. The adhesive member may include the second adhesive layer 280 and release films 281 and 282 on at least one surface of the second adhesive layer 280.

The release films 281 and 282 may at least temporarily protect an adhesive surface of the second adhesive layer 280 from contaminants such as dust, debris, and moisture. The release film 281 may be a film including or formed of polyimide (PI), polyethylene terephthalate (PET), polyethylene naphthalate (PEN), polyethersulfone (PES), nylon, polytetrafluoroethylene (PTFE), polyether ether ketone (PEEK), polycarbonate (PC), and/or polyarylate.

An adhesive force between the second adhesive layer 280 and a lower release film 281 may be in a range from 5 to 25 gf/in, and 15 gf/in on average. An adhesive force between the second adhesive layer 280 and an upper release film 282 may be in a range from 35 to 65 gf/in, and 50 gf/in on average.

After removing the lower release film 281 of the adhesive member, the adhesive member including the upper release film 282 and the second adhesive layer 280 is transferred onto the first flexible circuit board 240.

Referring to FIG. 9C, the adhesive member including the upper release film 282 and the second adhesive layer 280 is attached onto the first adhesive layer 270 which is attached to the first cover layer 242 of the first flexible circuit board 240 by applying a certain pressure for a predetermined time. In such a case, the adhesive force between the upper release film 282 and the second adhesive layer 280 increases.

Next, the upper release film 282 is removed.

Conventionally, when the upper release film 282 is removed, the adhesive force of the first adhesive layer 270 and the first cover layer 242 of the first flexible circuit board 240 is in a range from 0.3 kgf/inch to 1.5 kgf/inch which does not provide suitable or sufficient adhesive force, and accordingly, the second adhesive layer 280 may peel off along with the upper release film 282 from the first flexible circuit board 240 due to an increased adhesive force between the upper release film 282 and the second adhesive layer 280.

Since the first adhesive layer 270 according to an embodiment of the present disclosure provides an adhesive force greater than 2.0 kgf/in to the second adhesive layer 280, when the upper release film 282 is removed, the upper release film 282 does not peel off from the first adhesive layer 270, although the adhesive force between the upper release film 282 and the second adhesive layer 280 increases.

Referring to FIG. 9D, the second flexible circuit board 250 is attached onto the second adhesive layer 280. An adhesive force between the second adhesive layer 280 and the second flexible circuit board 250, more specifically, between the second adhesive layer 280 and the second cover layer 252, may be greater than 0.3 kgf/inch. For example, the adhesive force between the second adhesive layer 280 and the second flexible circuit board 250 may be in a range from 0.3 kgf/inch to 1.5 kgf/inch.

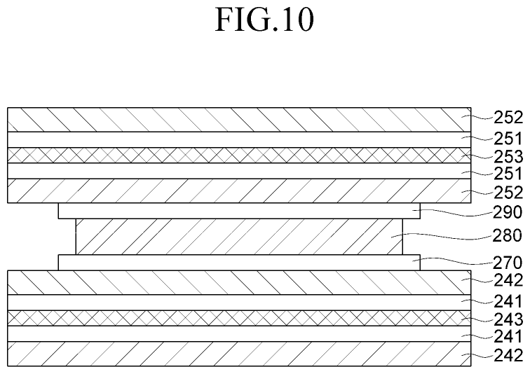

FIG. 10 is a partial cross-sectional view enlarging portion A of FIG. 3 in a display device according to another embodiment of the present disclosure. Components described hereinabove in the afore-mentioned embodiments of the present disclosure will be omitted, and different configurations will be mainly described.

Referring to FIG. 10, a first adhesive layer 270, a second adhesive layer 280, and a third adhesive layer 290 may be between a securing portion 260 and a first flexible circuit board 240 according to another embodiment of the present disclosure.

The third adhesive layer 290 may include or be formed of a material substantially the same as a material forming the first adhesive layer 270. That is, the third adhesive layer 290 may include a filler and a binder binding the filler to each other in the same manner as the first adhesive layer 270.

The filler may include at least one selected from the group consisting of BaSO₄, TiO₂, SiO₂, and carbon black. The filler may have a size in a range from 2 nm to 500 nm, and may have a circular shape, a rod shape, and/or an irregular shape.

The binder may include acrylic resins and/or epoxy resins.

In addition, the third adhesive layer 290 may further include a solvent capable of dissolving the binder. The solvent may be volatilized during the bonding process between the first flexible circuit board 240 and the second flexible circuit board 250 but may remain partially in the third adhesive layer 290.

The third adhesive layer 290 may be applied onto the second flexible circuit board 250 in a silk printing and/or deposition process in the same manner as the pattern illustrated in FIGS. 8A to 8C.

An adhesive force between the third adhesive layer 290 and the second flexible circuit board 250, more specifically, between the third adhesive layer 290 and the second cover layer 252, may be greater than about 1.5 kgf/in. For example, the adhesive force between the third adhesive layer 290 and the second flexible circuit board 250 may be in a range from about 1.5 kgf/in to about 2.5 kgf/in. The third adhesive layer 290 provides a greater adhesive force to the second adhesive layer 280 and the securing portion 260 of the second flexible circuit board 250.

An adhesive force between the third adhesive layer 290 and the second adhesive layer 280 may be greater than 2.0 kgf/in. For example, the adhesive force between the third adhesive layer 290 and the second adhesive layer 280 may be in a range from about 2.0 kgf/in to about 3.0 kgf/in.

The window 400 may include or be formed of a transparent material such as glass and/or resin and protect the display panel so that the display panel is not broken by an external impact. For example, the window 400 is on the touch portion 210 and covers the display area DA and the pad area PA. The window 400 is attached to the first substrate 110 and the second substrate 200 using the resin layer 230. Although the window 400 may be formed larger than the display panel, embodiments are not limited thereto, and the window 400 may be formed to have substantially the same size as the display panel.

The black matrix 410 is in an area of the window 400 corresponding to the pad area PA. The black matrix 410 includes a printing material that blocks or reduces visibility of a pattern underlying the window 400. In an embodiment, the black matrix 410 includes a light-absorbing material such as chromium (Cr).

The polarizing plate 220 is between the window 400 and the touch portion 210. The polarizing plate 220 prevents or reduces reflection of external light.

The resin layer 230 is between the window 400 and the touch portion 210, and improves the luminance, transmittance, reflectance, and visibility of the display device 10. In addition, the resin layer 230 is between the window 400 and the pad area PA of the first substrate 110. The resin layer 230 prevents or reduces formation of an air gap between the window 400 and the first substrate 110 and between the window 400 and the second substrate 200 and prevents or reduces penetration of foreign substances such as dust. The resin layer 230 may be a photocurable resin.

The embodiments of the display device described above are merely examples. The scope of the present disclosure is defined by the following claims, and equivalents thereof, rather than the above detailed description, and it should be interpreted that all changes or modified forms derived from the meaning, scope of the claims, and equivalent concepts thereof are included in the scope of the present disclosure.

1. A display device comprising:
a first flexible circuit board;
a securing portion protruding and extending from one side of the first flexible circuit board;
a first adhesive layer on the securing portion;
a second adhesive layer on the first adhesive layer; and
a second flexible circuit board on the second adhesive layer.

2. The display device of claim 1, wherein the first adhesive layer comprises:
a binder comprising an acrylic resin, and
a filler comprising at least one selected from the group consisting of BaSO₄, TiO₂, SiO₂, and carbon black,
wherein the second adhesive layer comprises a pressure sensitive adhesive.

3. A display device comprising:
a first substrate comprising a display area and a pad area;
a second substrate facing the first substrate;
a touch portion on the second substrate;
a first flexible circuit board coupled to the first substrate;
a second flexible circuit board coupled to the touch portion;
a securing portion extending from one selected from the first flexible circuit board and the second flexible circuit board;
a first adhesive layer between the securing portion and the other selected from the first flexible circuit board and the second flexible circuit board; and
a second adhesive layer between the first adhesive layer and the securing portion, and formed of a material different from a material that forms the first adhesive layer.

4. The display device of claim 3, wherein the first adhesive layer comprises:
a filler comprising particles having a size in a range from 2 nm to 500 nm; and
a binder binding the filler.

5. The display device of claim 4, wherein the filler comprises at least one selected from the group consisting of BaSO₄, TiO₂, SiO₂, and carbon black.

6. The display device of claim 4, wherein the binder comprises at least one selected from the group consisting of acrylic resins and epoxy resins.

7. The display device of claim 3, wherein the first adhesive layer has a thickness in a range from 5 to 15 μm.

8. The display device of claim 4, wherein the second adhesive layer comprises a pressure sensitive adhesive.

9. The display device of claim 3, wherein an adhesive force between the first adhesive layer and the second adhesive layer is in a range from about 2.0 kgf/in to about 3.0 kgf/in.

10. The display device of claim 3, wherein an adhesive force between the first adhesive layer and the first flexible circuit board is in a range from about 1.5 kgf/in to about 2.5 kgf/in.

11. The display device of claim 3, wherein the securing portion protrudes from one side of one selected from the first flexible circuit board and the second flexible circuit board.

12. The display device of claim 3, wherein the securing portion is formed by cutting and bending a portion of one selected from the first flexible circuit board and the second flexible circuit board.

13. The display device of claim 12, wherein the securing portion overlaps one side of one selected from the first flexible circuit board and the second flexible circuit board.

14. The display device of claim 3, wherein the securing portion is on a rear surface of the first flexible circuit board.

15. The display device of claim 3, further comprising:
a third adhesive layer between the second adhesive layer and the second flexible circuit board.

16. The display device of claim 15, wherein the third adhesive layer comprises a material substantially the same as a material that forms the first adhesive layer.

17. A display device comprising:
a first substrate comprising a display area and a pad area;
a second substrate facing the first substrate;
a touch portion on the second substrate;
a first flexible circuit board coupled to the first substrate;
a securing portion protruding and extending from one side of the first flexible circuit board;
a second flexible circuit board coupled to the touch portion;
a first adhesive layer on the securing portion; and
a second adhesive layer that attaches the first adhesive layer and the second flexible circuit board to each other,
wherein each of the first adhesive layer and the second adhesive layer comprises:
a first pattern defining an application area; and
a second pattern applied at a predetermined interval on the first flexible circuit board or on the second flexible circuit board in at least one of a horizontal direction and a vertical direction within the first pattern in a plan view.

18. The display device of claim 17, wherein the first adhesive layer comprises:
a filler comprising particles having a size in a range from 2 nm to 500 nm; and
a binder binding the filler.

19. The display device of claim 18, wherein the filler comprises at least one selected from the group consisting of BaSO₄, TiO₂, SiO₂, and carbon black.

20. The display device of claim 18, wherein the binder comprises at least one selected from the group consisting of acrylic resins and epoxy resins.
